(19) United States
(12) Patent Application Publication
(10) Pub. No.: US 2026/0032946 A1
(43) Pub. Date: Jan. 29, 2026

(54) SEMICONDUCTOR MEMORY DEVICE AND METHOD THEREOF

(71) Applicant: Micron Technology, Inc., Boise, ID (US)

(72) Inventor: Michael A. Smith, Boise, ID (US)

(21) Appl. No.: 19/275,685

(22) Filed: Jul. 21, 2025

Related U.S. Application Data
(60) Provisional application No. 63/674,658, filed on Jul. 23, 2024.

(51) Int. Cl. H10D 30/62; G11C 16/12; H10D 62/10

(52) U.S. Cl. CPC H10D 30/6211; G11C 16/12; H10D 62/102

(57) ABSTRACT

A semiconductor device is described in this disclosure. The semiconductor device includes a first semiconductor channel, a second semiconductor channel parallel to the first semiconductor channel, and a gate disposed above the first semiconductor channel and the second semiconductor channel. In addition, the semiconductor device includes a string driver and dummy devices coupled to the string driver, wherein dummy devices are biased at Vₚₐₛₛ to better emulate transistor bias behavior of the string driver by capturing the Vₜ/Dvₜ modulating effect of the Vₚₐₛₛ on the neighbor devices. Further, the semiconductor device is coupled with a program voltage regulator circuit to emulate neighbor bias effort on the string driver.

### CROSS-REFERENCE TO RELATED APPLICATION(S)

The present application claims priority to U.S. Provisional Patent Application No. 63/674,658, filed Jul. 23, 2024, the disclosure of which is incorporated herein by reference in its entirety.

### TECHNICAL FIELD

The present disclosure generally relates to semiconductor devices, and more particularly relates to n-channel high voltage string driver devices (fortissimo string driver, hereinafter “SDF”)) having five nodes, and a program voltage regulator circuit to which the SDF device is coupled.

### BACKGROUND

String driver is an electronic circuit or device that controls the operation of a series of memory cells arranged in a string. For example, in NAND flash memory, memory cells are organized into arrays and connected in series to form a string. The string driver is responsible for selecting and manipulating these strings during read, write, or erase operations of a memory device. Further, string drivers are often integrated with or connected to charge pumps that generate required high voltages from a lower voltage power supply. The string driver regulates these voltages and ensures that they are applied accurately to the memory cells during programming and erasing operations. Moreover, String drivers can enable or disable specific strings within an array for targeted operations, allowing the memory controller to interact with specific sections of the memory array. In memory devices including NAND flash memory arrays, dynamic random-access memory (DRAM) arrays, and/or phase change memory (PCM) arrays, string driver is primaried used for data storage, wear leveling, and error correction.

In scaled semiconductor devices, the interplay between adjacent transistors emerges as a significant point of concern. Such interactions encompass a variety of effects, with neighbor bias and coupling effects standing out as pivotal factors in the architectural design of contemporary semiconductor devices such as string driver. Managing these interactions is not merely beneficial but imperative for the creation of electronic systems that are both reliable and efficient. As semiconductor devices scaling continue, the complexity of these interactions escalates, necessitating sophisticated design strategies to mitigate their impact.

### BRIEF DESCRIPTION OF THE DRAWINGS

FIG. 1 is a top-down view of a five nodes SDF device layout in accordance with various embodiments of the present technology.

FIG. 2 is a schematic, cross-sectional side view of a five nodes SDF device in accordance with various embodiments of the present technology.

FIG. 3 shows voltage curves applied on a SDF device during charging and recovery phases in accordance with various embodiments of the present technology.

FIGS. 4A and 4B are schematic diagrams of a SDF device and a dummy transistor, respectively in accordance with various embodiments of the present technology.

FIG. 5 shows circuit diagram including a five nodes SDF device and its corresponding control circuit in accordance with various embodiments of the present technology.

FIG. 6 shows a SDF device layout in accordance with various embodiments of the present technology.

FIG. 7 is a schematic block diagram of a system that includes a semiconductor device configured in accordance with various embodiments of the present technology.

### DETAILED DESCRIPTION

In semiconductor memory devices, a string driver is a critical component that plays a significant role in the operation of memory arrays, for example in non-volatile memory technologies such as NAND flash memory. The structure of a string driver is generally designed to interface with a series of memory cells connected in series, forming what is known as a string. Each string typically consists of multiple memory cells, and the string driver can be connected to the string at one end. The string driver itself can include several transistors that are used to control the voltage levels applied to the string during various memory operations. Specifically, the string driver can be configured to be responsible for managing the flow of electrical signals that program, read, and erase the memory cells within a string. During a read or program operation, the string driver applies the appropriate voltage levels to the control gates of the memory cells via the word lines. For example, during a read operation, the voltage can be set to a level that allows the sensing circuitry to determine the state of each memory cell. During programming, higher voltage levels can be applied to change the state of the memory cells. The string driver can also provide protection against potential over-voltage conditions that could damage the memory cells. It ensures that the voltage levels remain within safe limits during all operations.

In modern integrated circuits such as advanced memory devices, where semiconductor devices are highly scaled, the interactions between adjacent transistors become critically important. The neighbor bias effect and coupling effects are two primary phenomena resulting from these interactions. These phenomena can markedly affect the behavior and performance of transistors in the circuit. The neighbor bias effect is a phenomenon in which the performance of a transistor is affected by the voltages present on transistors that are adjacent. This effect is especially prominent in integrated circuits where transistors are densely packed and share a same substrate or well. Similar to body effect, the neighbor bias effect can cause variations in the threshold voltage Vₜ of a transistor. This occurs when the potential of the substrate or well of a transistor is influenced by the operational states or voltages applied to adjacent transistors. Such variations can alter the required activation voltages, thereby impacting the switching characteristics of the transistors. Another consequence of the neighbor bias effect is the potential increase in leakage currents that flow between the source and drain of a transistor. This can be intensified by the substrate bias, which is in turn affected by the voltages on neighboring transistors. An increase in leakage currents can compromise the power efficiency of the circuit and lead to higher levels of heat generation. Additionally, adjacent electronic devices primarily interact through capacitive and inductive couplings, which may inadvertently introduce signal interference and circuit noise. For example, capacitive coupling arises when voltage fluctuations in one transistor generate current flows or voltage variations in a neighboring transistor. This interaction is facilitated by shared or proximate capacitive components of the transistors. High-speed circuits are particularly susceptible to this coupling effect, as swift changes in gate voltages can cause notable crosstalk among densely arranged device components.

Due to reasons described above, string driver neighbor bias effect is becoming increasingly significant as the semiconductor devices continue to scale down. This effect arises due to the diminishing pitch of string drivers, e.g., as the active spacing between devices shrinks, the interaction or coupling between adjacent string driver devices intensifies to a level that can no longer be disregarded. One of the most notable implications of this effect is its impact on the threshold voltage variation Dvₜ of string drivers during programming operations. Specifically, variations in the bias applied to neighboring devices can induce a change in Dvₜ that exceeds 400 millivolts. This is a substantial deviation, considering the precise voltage levels required for reliable device operation.

For illustration, during typical programming operations, the devices adjacent to string driver being programmed are elevated to a voltage level referred to as Vₚₐₛₛ, which is approximately 10 volts (V). Meanwhile, the string driver itself is subjected to a ramping voltage that can reach up to around 30V, known as Vprog. It is during this process that the difference in Dvₜ, attributable to the neighbor bias effect, becomes particularly dominant. The variety in Dvₜ can be 400 mV or more when comparing the effects of a 0V versus a 10V bias on the neighboring devices.

To model and predict this behavior, the default approach has been to construct SPICE models based on data where Dvₜ is measured with the neighboring devices at a 0V bias. However, this method may not accurately capture the complexities introduced by the neighbor bias effect under actual operating conditions, where neighboring devices are not at 0V. As a result, there is a growing need to refine these models to account for the dynamic interactions and voltage variations experienced during real operations, ensuring that the models remain robust and predictive of the actual behavior of string drivers in the presence of neighbor bias effects.

To solve the issues and challenges described above, the present technology introduces an innovative approach to emulate and analyze the neighbor bias effect in string driver circuits, which is a critical aspect of semiconductor device operation. This effect is inherently present due to the decreasing pitch between string drivers, which leads to the string driver device neighbor coupling. The present technology specifically addresses the challenge of replicating this effect in a controlled environment for the purpose of accurate analysis and improved circuit performance. A key aspect of the present technology lies in the utilization of SDF devices with dummy transistor devices in a program switch voltage V_{pgmsw} reference circuit. These SDF devices is used with dummy devices biased at Vₚₐₛₛ to better emulate transistor bias behavior of the string driver by capturing the Vₜ/Dvₜ modulating effect of the Vₚₐₛₛ on the neighbor devices. In the present technology, SDF devices and dummy devices are strategically incorporated to act as proxies for actual string drivers, thereby creating a model that closely mimics the real-world conditions under which string drivers operate. The inclusion of these dummy devices is a novel approach to simulate the neighbor bias effect, which is otherwise difficult to replicate in isolated testing scenarios. In particular, the present technology employs a five nodes string driver model to represent the complex interactions between string drivers in a semiconductor device. This model is designed to reflect the various electrical potentials and their interactions at different nodes within the string driver circuit. By doing so, the present technology provides a comprehensive framework for understanding and analyzing the neighbor bias effects in string driver device.

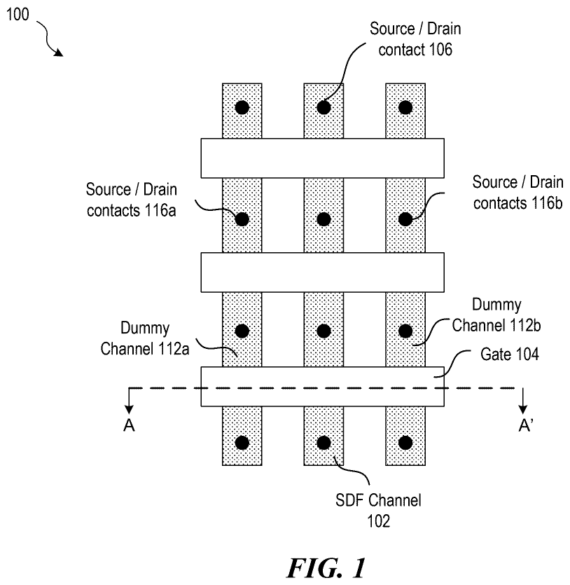

FIG. 1 illustrates a top-down view of a semiconductor SDF device 100 layout. In particular, the semiconductor SDF device 100 includes a string driver (SD) device disposed in the center and dummy devices disposed on the sides. As shown, the SDF device 100 is composed of a central SDF channel 102, flanked by a gate 104 and an array of source/drain contacts 106. Additionally, the SDF device 100 incorporates dummy channels 112a and 112b, along with their respective source/drain contacts 116a and 116b, positioned on either side of the SDF channel 102 to emulate the influence of neighboring device components. As shown, the gate 104 is strategically situated above the SDF channel 102 and the dummy channels 112a and 112b, which are aligned parallel to the SDF channel 102. These dummy channels 112a and 112b, as well as the SDF channel 102, are separated by local dielectric isolation and are interconnected to a well region (not shown) within a substrate of the SDF device 100.

To accurately represent the effects of adjacent SD devices operating at an elevated voltage level, such as a Vₚₐₛₛ near 10V, the source and drain regions associated with the dummy channels 112a and 112b are electrically wired up and linked to a pass voltage source via the source/drain contacts 116a and 116b. This configuration effectively creates a fifth node within the SDF device 100, simulating the bias imparted by neighboring string driver transistors on the body effect of the target string driver transistor. In this example, the Vₚₐₛₛ voltage is applied to the dummy channels 112a and 112b, respectively through source/drain contacts 116a and 116b. The biased dummy channels 112a and 112b, along with the source and drain regions associated with them, exert an influence on the magnitude of the body effect of the SDF transistor, which includes the SDF channel 102 and source and drain connected to it, through neighboring bias effects and cross-coupling effects.

In some examples, the SDF device 100 is designed with a dummy transistor structure adjacent to only one side of the SDF channel 102. For example, the SDF device 100 includes the SDF channel 102, the gate 104, the source/drain contact 106, and the dummy channel 112a, along with source/drain contacts 116a for the dummy channel 112a. A deep trench local isolation may serve to electrically isolate the dummy channel 112a from the SDF channel 102. The source and drain regions associated with the dummy channel 112a can be connected to a voltage source via the source/drain contacts 116a. In alternative examples, the SDF device 100 may include the dummy channel 112b with corresponding source and drain regions, which are also electrically isolated from the SDF channel 102 by deep trench local isolation. These source and drain regions can be linked to a different voltage source through the source/drain contacts 116b.

In this example, the source and drain regions connected to dummy channels 112a and/or 112b would be wired separately from the active string driver device regions e.g., the SDF channel 102 and source/drain contact 106. Specifically, the source and drain contacts 116a and 116b can be wired out to an external controlling circuit.

In some other examples, the SDF device 100 can incorporate multiple dummy channels aligned parallel to and on one side of the SDF channel 102. Each set of source/drain contacts associated with these dummy channels can be connected to a voltage source through their respective source/drain contacts. It is possible to configure each dummy channel and its connected source/drain regions to interface with a distinct voltage level. For instance, a first dummy channel situated immediately adjacent to the SDF channel 102 may be connected to a voltage source at a first voltage level (e.g., 10V) through its source/drain contacts. A second dummy channel, placed next to the first and further from the SDF channel 102, could be connected to a voltage source at a second voltage level (e.g., 9V) through its source/drain contacts. Similarly, a third dummy channel, located next to the second, may have its source/drain contacts connected to a voltage source at a third voltage level (e.g., 8V). In scenarios where dummy channels are symmetrically positioned relative to the SDF channel 102, their source/drain contacts may be connected to voltage sources at comparable voltage levels.

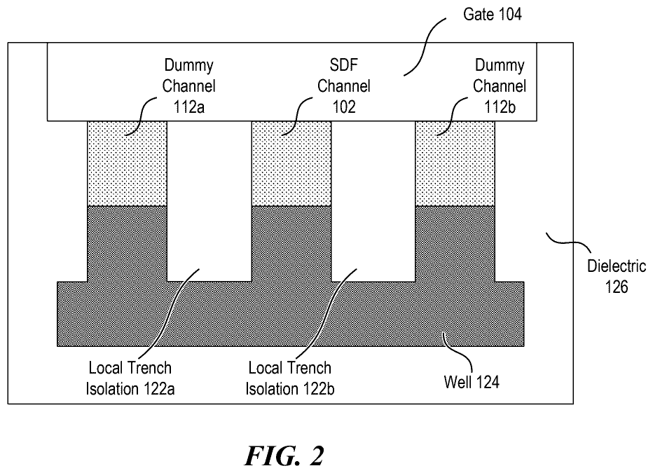

FIG. 2 is a schematic, cross-sectional side view of the five nodes SDF device 100 along the A-A′ plane noted in FIG. 1. As shown, the SDF devices 100 includes the SDF channel 102, and dummy channels 112a and 112b disposed on both sides of the SDF channel 102. In addition, the dummy channels 112a and 112b are separated from the SDF channel 102 by the local trench isolation 122a and 122b, respectively. Further, the gate 104 is disposed above and passes through the dummy channel 112a, the SDF channel 102, and the dummy channel 112b. In this example, the SDF device 100 includes a well 124, which is a doped region within the substrate of the SDF device 100 and has opposite conductivity type to the substrate. The well 124 helps isolate the SDF transistors from other components on the substrate and allows for the integration of both N-channel and P-channel transistor on the same substrate. Specifically, the type and concentration of doping in well 124 can affect the threshold voltage of the SDF transistors, which is needed to create a conducting path between the source and drain terminals. In SDF device 100, the well 124 can be electrically connected to a specific voltage to ensure proper operation and to prevent unwanted electrical behaviors. For example, the well 124 can be connected to a surface of the SDF device 100 to ensure the entire well 124 is at the same potential, through a well tap (e.g., a metal connection). Alternatively, the well 124 can be connected to a ground pad using metal interconnects. This external ground can serve as a reference point and a sink for any parasitic currents that might accumulate in the well 124. Moreover, the components of the SDF device 100 can be encapsulated by a dielectric 126, which can be composed of silicon oxide (SiO), silicon nitride (SiN), silicon borocarbonitride (SiBCN), silicon oxycarbonitride (SiOCN), silicon oxycarbide (SiOC), silicon carbonitride (SiCN), silicon boronitride (SiBN), a low-k dielectric material, or a combination thereof.

In this example, the local trench isolation 122a and 122b can be local deep trench (LDT) regions that further extend along a vertical direction of the SDF device 100 to completely cover side wall surfaces of the SDF channel 102 and dummy channels 112a and 112b. The local trench isolation 122a and 122b can be filled by electrically non-conductive materials including tetraethyl orthosilicate (TEOS), silicon oxide (SiO), silicon nitride (SiN), silicon borocarbonitride (SiBCN), silicon oxycarbonitride (SiOCN), silicon oxycarbide (SiOC), silicon carbonitride (SiCN), silicon boronitride (SiBN), a low-k dielectric material, or a combination thereof. It should be appreciated that in this disclosure of the present technology, neighbors correspond to other string drivers in a large block of string drivers. Specifically, each string driver passes voltages to a different tier of the array in a memory device. The neighbors being biased to Vₚₐₛₛ is a product of the memory array tier biasing scheme.

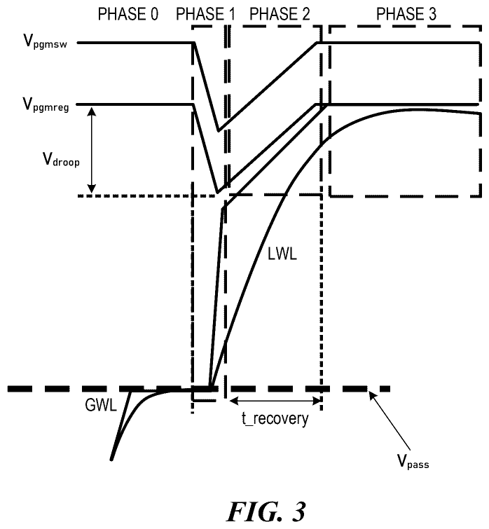

FIG. 3 illustrates voltage curves applied on a memory device during charging and recovering of SD devices in accordance with various embodiments of the present technology. Specifically, the SD devices connect/disconnect a global wordline (GWL), corresponding to a particular array tier, to a local wordline (LWL). The string driver devices are controlled by the program switch voltage (V_{pgmsw}), which is applied to their gates, and the word line program voltage (V_{pgmreg}), which is passed through to the word lines by the string driver devices. In this example, the word lines are divided into GWL and LWL, which are selectively activated for different memory operations. As shown, the programming of a memory device involves four phases: phase 0, phase 1, phase 2, and phase 3. During phase 0, all SD devices in the selected block are biased to a pass voltage Vₚₐₛₛ (e.g., GWL=LWL=Vₚₐₛₛ, V_{g}=Vₚₐₛₛ+ΔV), and the program pump is regulated to desired V_{pgmreg}/V_{pgmsw} outputs. In some examples, the pass voltage Vₚₐₛₛ ranges from 8V to 15V, preferably close to 10V. At phase 1, a switch in the path between the program pump and the program wordline is thrown to switch the input to the target program string driver from Vₚₐₛₛ to Vpgm (GWL) and V_{pgmsw} (gate). This sudden switch causes the output of the regulator/pump to droop temporarily while GWL voltage starts to rise quickly, and LWL voltage rises less quickly due to the resistance of the string driver and RC of the path to the wordline. Phase 2 is the recovery phase after the droop, when V_{pgmsw} and V_{pgmreg} start to recover to their regulated values. During phase 2, GWL voltage rises less quickly (e.g., it is very close to V_{pgmreg}, only reduced due to an IR drop in the path). In addition, LWL voltage continues to ramp in this phase. Phase 3 occurs when V_{pgmsw} and V_{pgmreg} are settled at their regulated voltages, and the GWL voltage is close to V_{pgmreg}. In this phase, LWL voltage continues to rise but more slowly, and asymptotically approaches GWL voltage and V_{pgmreg}. During phases 1-3, the string drivers neighboring the program string driver remain biased at the pass voltage Vₚₐₛₛ (e.g., GWL voltage=LWL voltage=Vₚₐₛₛ, although due to the shared continuous gate, their V_{g} of course is also V_{pgmsw}). Here, this bias arrangement motivates the adoption of the 5-node SDF device with dummies biased to Vₚₐₛₛ to applications described in this disclosure.

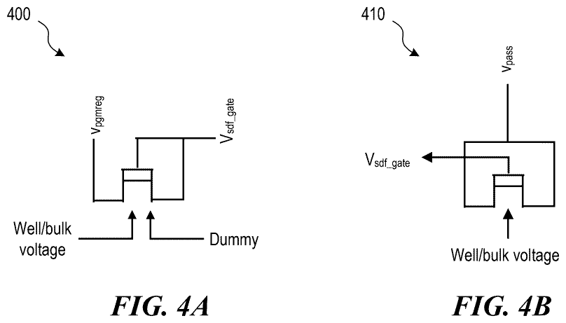

FIGS. 4A and 4B are schematic diagrams of a five nodes SDF device 400 and a dummy transistor 410 included therein respectively. The five nodes SDF device 400 comprises a gate (first node), a source (second node), a drain (third node), a well (fourth node), and a dummy terminal (fifth node). The dummy terminal is formed by wiring up source and drain contacts of the dummy transistor 410. The dummy terminal can be electrically connected to a voltage source, such as the Vₚₐₛₛ voltage. The five nodes SDF device 400 can have a similar structure to the SDF device 100 shown in FIGS. 1 and 2. In addition, the well/bulk of the SDF device 400 can be connected to a separate well/bulk voltage. The gate and source (or drain) of the SDF device 400 are both connected to the program switch voltage Vsdf_gate, which controls the programming operation of the memory cells. Moreover, the drain (or source) of the SDF device 400 is connected to the word line program voltage V_{pgmreg}, which is applied to the selected word line of the memory array during programming.

In this example, the dummy transistor 410 is integrated in the five nodes SDF device 400 and has four nodes. The gate of the dummy transistor 410 is shared with the gate of the SDF device 400 and is also connected to the program switch voltage Vsdf_gate. The source and drain of the dummy transistor 410 are wired up and electrically connected to the word line program voltage V_{pgmreg}. As described earlier, the dummy transistor 410 can act as a capacitive load for the SDF device 400 and can help to simulate the coupling biases across the SDF device 400 during programming.

In some examples, the five nodes SDF device 400 may include more than one dummy transistor, such as another dummy transistor 420 disposed on the opposite side of the string driver channel of the SDF device 400. The additional dummy transistor 420 can have the same structure and connections as the dummy transistor 410 and can further enhance the neighboring bias effects on the SDF device 400. In some other examples, the five nodes SDF device 400 may include multiple dummy transistors that are symmetrically aligned on either side or both sides of the string driver channel of the SDF device 400, depending on the design and layout of the memory device. The number and arrangement of the dummy transistors can be adjusted to optimize the performance and reliability of the five nodes SDF device 400 and the memory device.

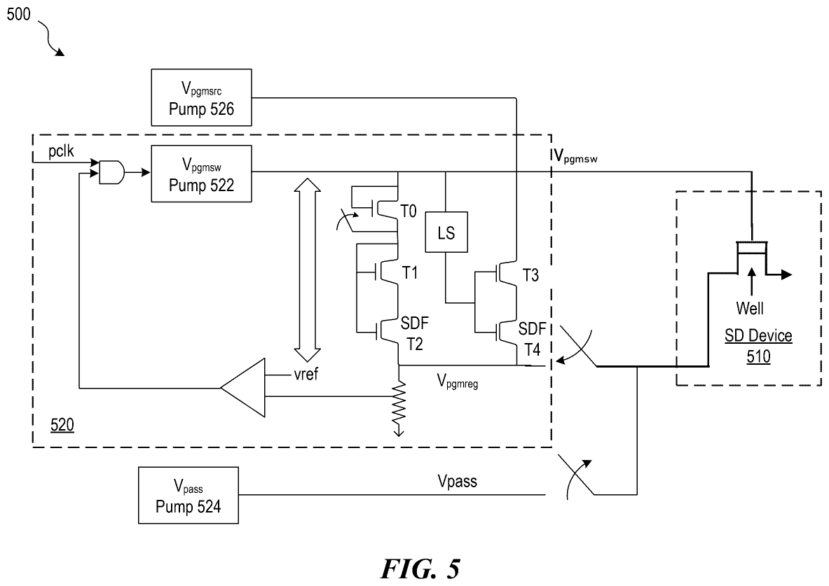

FIG. 5 shows circuit diagram 500 including one or more SD devices 510 and corresponding control circuit 520. Each one of the SD devices 510 includes a SD channel, a gate terminal, source and drain terminal, and a well terminal. In this example, each SD device of the SD devices 510 may be affected by a neighbor bias effect induced by adjacent SD devices. In this example, the SD devices 510 can be connected in serial, e.g., having commonly connected gate terminals and having a drain terminal of one SD device connected to a source terminal of an adjacent SD device. As shown, the gate terminal of the SD device 510 is connected to the V_{pgmsw}, which is a high voltage generated by the control circuit 520 to enable the programming operation. In this example, the source terminal of the SD device 510 is electrically connected to the V_{pgmreg}, which is a regulated voltage that controls the current flow through the SD device 510. By configurating the switches connected to the source terminal of the SD device 510, the Vₚₐₛₛ voltage can also be applied to the SD device 510.

In this example, the control circuit 520 can be operated as a V_{pgmreg} voltage regulator circuit. Further, the control circuit 520, in combination with the SD device 510, is configured to mirror a Vₜ/DVₜ behavior of a string driver device such that the output voltages including V_{pgmreg} voltage and V_{pgmsw} voltage are appropriate for operations of the SD devices 510. As shown, the control circuit 520 includes a V_{pgmsw} voltage pump 522 that provides the V_{pgmsw} voltage by boosting the pclk signal. In addition, the control circuit 520 is connected to a V_{pgmsrc} voltage pump 526 and a Vₚₐₛₛ voltage pump 524, which provide the V_{pgmreg} voltage and the Vₚₐₛₛ voltage, respectively. The Vₚₐₛₛ is a voltage applied to the gates of the memory cells in the string to allow them to pass the programming current. In this example, the control circuit 520 also receives a Vref signal, which is a reference voltage that determines the threshold voltage of the programmed memory cells.

In this example, the circuit diagram 500 includes the SD devices 510 that each can pass a programming voltage V_{pgmreg} to a local wordline of a memory device, such as a NAND device. The program voltage V_{pgmreg} is configured to pass the channel of each of the SD devices 510 through its source terminal and its drain terminal. The programming voltage V_{pgmreg} can vary from 15V to 30V depending on the memory device requirements. In some examples, the channel of each of the SD devices 510 is a n-type channel, and the program voltage V_{pgmreg} is transferred from a program voltage source to its source terminal.

To pass V_{pgmreg} across any high voltage NMOS (HVN) devices, such as device T1 and device T3 shown on FIG. 5, the control circuit 520 respectively connects the device T1 or T3 in serial to SDF device T2 and SDF device T4. In this example, each of the SDF device T2 and T4 has dummy transistor devices coupled thereon. For example, besides the gate terminal, the source and drain terminal, the well terminal, the SDF device T2 and T4 each also includes and a dummy terminal (e.g., the dummy terminal described in FIGS. 4A and 4B). The SDF device T2 or T4 shares the gate voltage Vsdf_gate with corresponding dummy transistor device through a continuous gate crossing the SDF device and the coupled dummy device. Additionally, the control circuit 520 is configured to generate a switch voltage V_{pgmsw} that is higher than V_{pgmreg} by the gate-to-source voltage (V_{gs}) of the HVN device. Further, the V_{gs} of the HVN device is determined by its threshold voltage Vₜ and its overdrive voltage Vₒᵥ, which is minimized to reduce power consumption. The control circuit 520 also ensures that the Vₜ of the SD device 510 is high enough to prevent leakage current and that the V_{pgmsw} is limited to 31.5V to avoid exceeding the high voltage specification (HV spec) of the HVN device. The control circuit 520 utilizes the V_{pgmsw} voltage pump 522 to boost the V_{pgmsw} voltage from the reference voltage Vref, and the Vₚₐₛₛ pump 524 to boost the pass voltage Vₚₐₛₛ from the pump clock pclk, and the V_{pgmsrc} voltage pump 526 to boost the V_{pgmsw} voltage from the Vₚₐₛₛ. In some examples, the gate voltage Vsdf_gate on the SDF devices T2 and T4 is slightly different from the V_{pgmsw} due to the voltage drop across the transistor TO upstream of T1 which may or may not be shunted.

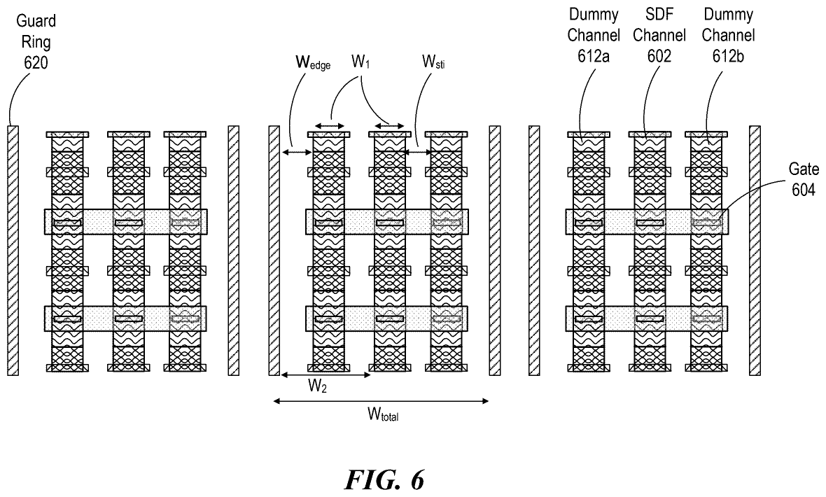

FIG. 6 shows a layout of SDF devices 600 in accordance with various embodiments of the present technology. In this example, each of the SDF devices 600 includes three channels aligned in parallel, including a dummy channel 612a, a SDF channel 602, and a dummy channel 612b. A gate 604 is disposed above and shared among the dummy channels 612a and 612b, and the SDF channel 602. As shown, the dummy channels 612a and 612b are disposed on both sides of the SDF channel 602. In some examples, the width W₁ of the SDF channel 602 and the dummy channels 612a and 612b can be identical or close to each other, e.g., W₁ close to 14 μm. In some other examples, the channel width W₁ can ranges from 1 μm to 50 μm. Alternatively, the width of the dummy channels 612a and 612b can be smaller than that of the SDF channel 602.

As shown in FIG. 6, the SDF channel 602 is separated from each of the dummy channels 612a and 612b by dielectric isolation such as shallow trench isolations (STI). In this example, the width of STI disposed between the dummy channel 612a or 612b to the SDF channel 602, e.g., Wₛₜᵢ, can be close to 5 μm. In some other examples, Wₛₜᵢ can range from 1 μm to 20 μm. In this example, FIG. 6 illustrates that three SDF devices 600 are horizontally aligned and separated from each other by dielectric isolation. In some other examples, a string driver circuit may include up to hundreds of SDF devices 600 that are horizontally and/or vertically aligned in the string driver device layout.

In this example, each of the SDF devices 600 includes guard rings 620 disposed in edge regions. For example, the guard rings 620 can be disposed parallel to the dummy channels 612a and 612b, and further from the SDF channel 602. Here, the guard rings 620 is configured to isolate the active region of the SDF device 600 from other components or devices on the same substrate, preventing electrical interference and reduces the risk of latch-up. In addition, by surrounding the guard rings 620 in edge regions of each of the SDF devices 600, any leakage currents within the SDF devices 600 can be confined and prevented from spreading to other parts of the circuit. Here, guard rings 620 can be formed from the same type of semiconductor material as the rest of the device (e.g., silicon), and/or are heavily doped to create either a p-type or n-type region, depending on the overall device structure. In this example, the pitch distance between parallelly aligned guard rings 620 Wₜₒₜ can be close to 62 μm. In some other examples, the pitch distance Wₜₒₜ ranges from 10 μm to 200 μm. Additionally, the edge distance W_{edge} from the dummy channel 612a or 612b to corresponding guard ring 620 can be close to 5 μm. Further, the distance W₂ from the SDF channel 602 and corresponding guard ring 620 can be close to 28 μm.

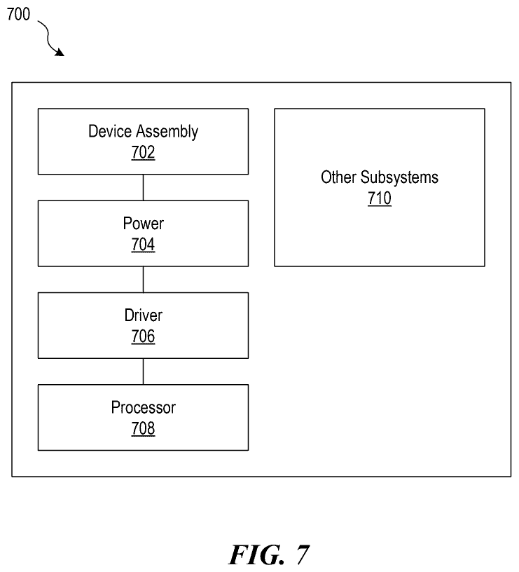

Any one of the SDF devices and semiconductor device assemblies described above with reference to FIGS. 1 to 6 can be incorporated into any of a myriad of larger and/or more complex systems, a representative example of which is system 700 shown schematically in FIG. 7. The system 700 can include a semiconductor device assembly (e.g., or a discrete semiconductor device) 702, a power source 704, a driver 706, a processor 708, and/or other subsystems or components 710. The semiconductor device assembly 702 can include features generally similar to those of the five nodes SDF devices described above with reference to FIGS. 1 to 6. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances and other products. Components of the system 900 may be housed in a single unit or distributed over multiple, interconnected units (e.g., through a communications network). The components of the system 700 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a first semiconductor channel;
a second semiconductor channel parallel to the first semiconductor channel;
a gate disposed above the first semiconductor channel and the second semiconductor channel;
a well disposed underneath the first semiconductor channel and the second semiconductor channel;
a first source and a first drain that are electrically connected to the first semiconductor channel, wherein a program voltage is configured to pass the first semiconductor channel through the first source and the first drain; and
a second source and a second drain that are electrically connected to the second semiconductor channel, wherein the second source and the second drain are wired up and electrically connected to a pass voltage source.

2. The semiconductor device of claim 1, further comprising a first local deep trench isolation that separates the first semiconductor channel and the second semiconductor channel.

3. The semiconductor device of claim 1, wherein the first semiconductor channel is a n-type channel, and the program voltage is transferred from a program voltage source to the first source.

4. The semiconductor device of claim 3, wherein the program voltage is provided by the program voltage source, the program voltage being ranging up to 30V.

5. The semiconductor device of claim 1, further comprising a gate contact electrically connected to the gate, the gate contact being connected with a program switch voltage source.

6. The semiconductor device of claim 5, wherein the program switch voltage source is configured to provide a program switch voltage ranging up to 31.5V.

7. The semiconductor device of claim 1, further comprising:
a first source contact and a first drain contact that are electrically connected to the first source and the first drain respectively; and
a second source contact and a second drain contact that are electrically connected to the second source and the second drain respectively,
wherein the second source and the second drain are wired up respectively through the second source contact and the second drain contact.

8. The semiconductor device of claim 1, further comprising:
a third semiconductor channel parallel to the first semiconductor channel and disposed on an opposite side to the second semiconductor channel; and
a third source and a third drain that are electrically connected to the third semiconductor channel, wherein the third source and the third drain are wired up with the second source and the second drain, and the third source and the third drain are electrically connected to the pass voltage source.

9. The semiconductor device of claim 8, further comprising a third source contact and a third drain contact that are electrically connected to the third source and the third drain respectively, wherein the third source and the third drain are wired up respectively through the third source contact and the third drain contact.

10. The semiconductor device of claim 8, further comprising a second local deep trench isolation that separates the first semiconductor channel and the third semiconductor channel.

11. The semiconductor device of claim 1, further comprising a guard ring disposed at edge of the semiconductor device.

12. A high voltage string driver (SDF) device, comprising:
a first string driver transistor comprising a first semiconductor channel, a first source and a first drain electrically connected to the first semiconductor channel, wherein a program voltage is configured to pass the first semiconductor channel through the first source and the first drain; and
a second dummy transistor comprising a second semiconductor channel, a second source and a second drain electrically connected to the second semiconductor channel,
wherein the second semiconductor channel is parallel to the first semiconductor channel and isolated by a first local deep trench isolation,
wherein the first string driver transistor and the second dummy transistor share a gate that is disposed above the first semiconductor channel and the second semiconductor channel, and
wherein the second source and the second drain are wired up and electrically connected to a pass voltage source.

13. The SDF device of claim 12, further comprising:
a third dummy transistor comprising a third semiconductor channel, a third source and a third drain electrically connected to the third semiconductor channel,
wherein the third semiconductor channel is parallel to the first semiconductor channel and disposed on an opposite side to the second semiconductor channel.

14. The SDF device of claim 13, further comprising a second local deep trench isolation that separates the first semiconductor channel and the third semiconductor channel.

15. The SDF device of claim 13, wherein the third source and the third drain are wired up with the second source and the second drain, and the third source and the third drain are electrically connected to the pass voltage source.

16. An electronic system, comprising:
a program voltage regulator circuit, comprising:
a program switch voltage source configured to provide a program switch voltage,
a program voltage source configured to provide a program voltage, and
a pass voltage source configured to provide a pass voltage; and
a high voltage string driver (SDF) device, comprising:
a gate node electrically connected to the program switch voltage source of the program voltage regulator circuit,
a source node and a drain node, one of the source node and the drain node being electrically connected to the program voltage source,
a body node connected with a substrate of the string driver circuit, and
a dummy node electrically connected to the pass voltage source, the dummy node being connected with a first dummy source and a first dummy drain of the SDF device.

17. The electronic system of claim 16, wherein the SDF device further comprising:
a first semiconductor channel, to which the gate node, the source node and the drain node are electrically connected; and
a second dummy semiconductor channel, to which the dummy node is electrically connected,
wherein the first semiconductor channel and the second dummy semiconductor channel are aligned in parallel and isolated by a first deep trench isolation.

18. The electronic system of claim 17, wherein the gate node is connected with the first semiconductor channel and the second dummy semiconductor channel.

19. The electronic system of claim 17, further comprising a third dummy semiconductor channel, to which the dummy node is electrically connected, wherein the first semiconductor channel and the second dummy semiconductor channel are aligned in parallel and isolated by a second deep trench isolation.

20. The electronic system of claim 16, wherein the program switch voltage ranges up to 31.5V, the program voltage ranges up to 30V, and the pass voltage ranges from 8V to 15V.
